(19) United States
(12) Patent Application Publication
(10) Pub. No.: US 2017/0104507 A1
(43) Pub. Date: Apr. 13, 2017

(54) ADJUSTING LOCAL OSCILLATOR FREQUENCY DURING GAPS IN DATA TRANSMISSION

(71) Applicant: QUALCOMM Incorporated, San Diego, CA (US)

(72) Inventors: Udara Charman Fernando, San Diego, CA (US); Ketan Humnabadkar, San Diego, CA (US); Tsai-Chen Huang, San Diego, CA (US); Tony Chang, Irvine, CA (US)

(21) Appl. No.: 14/880,064

(22) Filed: Oct. 9, 2015

(51) Int. Cl. H04B 1/16; H03D 7/14

(52) U.S. Cl. CPC H04B 1/16; H03D 7/1466

(57) ABSTRACT

A receiver, including: a local oscillator (LO) configured to generate a signal with a frequency; a mixer coupled to the LO, the mixer configured to change a first frequency of an input signal to a second frequency based on the generated signal; a baseband filter coupled to the mixer and having a bandwidth; and a controller coupled to the local oscillator, the controller configured to adjust the frequency of the signal to shift the second frequency of the input signal to a third frequency in response to a presence of one or more intra-band jammers that fall within the bandwidth of the baseband filter so that a respective image of the one or more intra-band jammers avoids failing into a respective one of a plurality wanted signals in the input signal.

### BACKGROUND

Field

This disclosure relates generally to adjusting local oscillator frequency, and more specifically, to adjusting local oscillator frequency in the presence of intra-band jammers.

Background

To meet increasing downlink (DL) data rate requirements, band combination numbers for the carrier aggregation (CA) may continue to grow. For DL CA applications, a receiver (Rx) architecture complexity may be heavily dependent on a circuit topology to manage a non-contiguous intra-band CA operation since multi-carriers within a duplexer bandwidth may need to be processed simultaneously using a single RF input port. However, the “one-input multi-output” signal processing poses challenges on the architecture development to simultaneously achieve low noise figure (NF) and high linearity, while controlling power and area consumptions. A conventional design for a “low noise amplifier (LNA) split” architecture to complete the non-contiguous intra-band CA operation may limit the total band combination numbers for the CA to four DLs. Accordingly, a zero intermediate frequency (ZIF) wideband receiver that digitizes multiple carriers in a single analog-to-digital converter (ADC) may experience desense due to strong in-band jammers falling at the image of the wanted signal.

### SUMMARY

The present disclosure describes various implementations of circuits, apparatus, and methods for adjusting a local oscillator frequency in the presence of intra-band jammers.

In one embodiment, a receiver is disclosed. The receiver includes: a local oscillator (LO) configured to generate a signal with a frequency; a mixer coupled to the LO, the mixer configured to change a first frequency of an input signal to a second frequency based on the generated signal; a baseband filter coupled to the mixer and having a bandwidth; and a controller coupled to the local oscillator, the controller configured to adjust the frequency of the signal to shift the second frequency of the input signal to a third frequency in response to a presence of one or more intra-band jammers that fall within the bandwidth of the baseband filter so that a respective image of the one or more intra-band jammers avoids failing into a respective one of a plurality wanted signals in the input signal.

In another embodiment, a method of adjusting a local oscillator frequency in the presence of intra-band jammers is disclosed. The method includes: receiving an indication of presence of one or more intra-band jammers that fall within a bandwidth of a baseband filter; and adjusting the local oscillator frequency in response to the presence of the intra-band jammers that fall within the bandwidth of the baseband filter so that images of the one or more intra-band jammers avoid falling on one of a plurality of wanted signals in an input signal.

In yet another embodiment, an apparatus for adjusting a local oscillator frequency in the presence of intra-band jammers is disclosed. The apparatus includes: means for receiving an indication of presence of one or more intra-band jammers that fall within a bandwidth of a baseband filter; and means for adjusting the local oscillator frequency in response to the presence of the one or more intra-band jammers that fall within the bandwidth of the baseband filter so that images of the intra-band jammers avoid falling on one of a plurality of wanted signals in an input signal.

Other features and advantages of the present disclosure should be apparent from the present description which illustrates, by way of example, aspects of the disclosure.

### BRIEF DESCRIPTION OF THE DRAWINGS

The details of the present disclosure, both as to its structure and operation, may be gleaned in part by study of the appended further drawings, in which like reference numerals refer to like parts, and in which:

FIG. 1A shows a single receiver architecture including a jammer signal in the presence of a primary component carrier (PCC) and a secondary component carrier (SCC) of a wanted signal;

FIG. 1B shows a two receiver case in which the jammer signal does not affect the wanted signal, because the PCC of the wanted signal is processed by one receiver (i.e., Receiver 1), while the SCC of the wanted signal is processed by another receiver (i.e., Receiver 2).

FIG. 2 is an exemplary wireless device communicating with a wireless communication system;

FIG. 3 is a functional block diagram of an exemplary design of a wireless device that is one embodiment of a wireless device of FIG. 2;

FIG. 4 shows a single receiver case in which the LO frequency is re-programmed in response to the presence of intra-band jammers along with a non-contiguous intra-band PCC and a non-contiguous intra-band SCC of a wanted signal;

FIG. 5 shows re-programming of the LO frequency performed during gaps in the data transmission by shifting the LO frequency from a first frequency to a second frequency;

FIG. 6A is a functional block diagram of an exemplary design of a wireless device that is one embodiment of a wireless device of FIG. 2;

FIG. 6B is a functional block diagram of a wireless device in accordance with an alternative embodiment of the present disclosure;

FIG. 7 is a functional block diagram of a receiver in accordance with one embodiment of the present disclosure; and

FIG. 8 is a functional flow diagram illustrating a method for adjusting the LO frequency in the presence of intra-band jammers in accordance with one embodiment of the present disclosure.

### DETAILED DESCRIPTION

To address the issues with in-band jammers falling inside the image of the wanted signal for a ZIF wideband receiver that digitizes multiple carriers in a single ADC, a local oscillator (LO) frequency of a receiver (Rx) can be re-programmed or re-tuned to a different frequency. However, re-programming the LO frequency of the Rx during data reception may cause throughput loss. Therefore, the LO frequency of the Rx can be re-programmed during gaps in the data transmission. For example, re-programming of the LO frequency can be done during following gaps so that the throughput is not affected: (1) during the sleep mode of a connected discontinuous reception (CDRx) cycle; (2) during cyclic prefix (CP) of an orthogonal frequency division multiplexing (OFDM) symbol using fast hopping phase-locked loop (PLL) to save power. However, since above-cited gaps are examples, re-programming of the LO frequency can be done during any gap in the data transmission. For example, the gaps in the data transmission may be gaps used in inter, intra, or inter-radio access technologies (inter-RAT) frequency measurements. In another example, the gaps in the data transmission may be gaps scheduled by a base station or detected by a user equipment (UE).

After reading this description it will become apparent how to implement the disclosure in various implementations and applications. Although various implementations of the present disclosure will be described herein, it is understood that these implementations are presented by way of example only, and not limitation. As such, this detailed description of various implementations should not be construed to limit the scope or breadth of the present disclosure.

The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

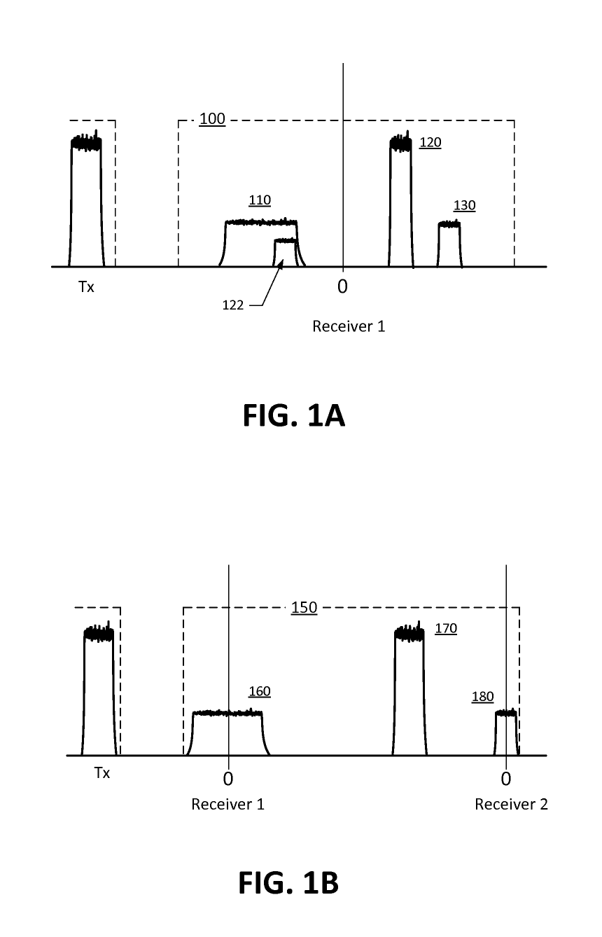

As stated above, a ZIF wideband receiver that digitizes multiple carriers in a single analog-to-digital converter (ADC) may experience desense due to strong in-band jammers falling at the image of the wanted signal. For example, FIG. 1A shows a single receiver architecture 100 including a jammer signal 120 in the presence of a primary component carrier (PCC) 110 and a secondary component carrier (SCC) 130 of a wanted signal. However, in the single receiver architecture 100 of FIG. 1A, a residual sideband (RSB) image 122 of the jammer 120 is present inside the PCC 110 of the wanted signal. RSB is a measure of gain imbalance and/or phase imbalance between an in-phase (I) signal path and a quadrature (Q) signal path in a receiver. In an ideal receiver, the I signal path should be 90 degrees out of phase with respect to the Q signal path, and the two signal paths should have equal gain across frequency. However, I/Q imbalance may exist between the I and Q signal paths and may include gain imbalance and/or phase error. I/Q imbalance results in RSB, which is distortion that falls on nearby frequencies.

Thus, in FIG. 1A, wanted signals 110, 130 are to be received and decoded by the receiver (i.e., Receiver 1), while jammer signal 120 having amplitudes that are much larger than that of the wanted signals 110, 130 and located close in frequency to the wanted signals is to be avoided. As shown in FIG. 1A, I/Q imbalance in the receiver may result in the jammer signal 120 causing the RSB image 122 that appears on the wanted signal 110. The RSB image 122 from the jammer acts as noise/interference to the wanted signal 110, which may adversely impact the ability to decode the wanted signal 110. The amplitude of the RSB image 122 is dependent on the received power level of the jammer signal 120 and the amount of I/Q imbalance in the receiver. The receiver has a noise floor, which may be determined by thermal noise as well as noise of circuits in the receiver. The RSB image 122 may be higher than the noise floor at the receiver. In this case, a carrier-to-noise ratio (C/N) of the wanted signal 110 may be limited by the RSB image 122 due to the jammer signal 120.

One conventional solution is to use multiple receivers, wherein each receiver digitizes a single carrier. For example, FIG. 1B shows a two receiver case 150. In this case, the jammer signal 170 does not affect the wanted signal, because the PCC 160 of the wanted signal is processed by one receiver (i.e., Receiver 1), while the SCC 180 of the wanted signal is processed by another receiver (i.e., Receiver 2). However, for a ZIF wideband receiver that digitizes multiple carriers in a single ADC, a multiple receiver solution may not be viable.

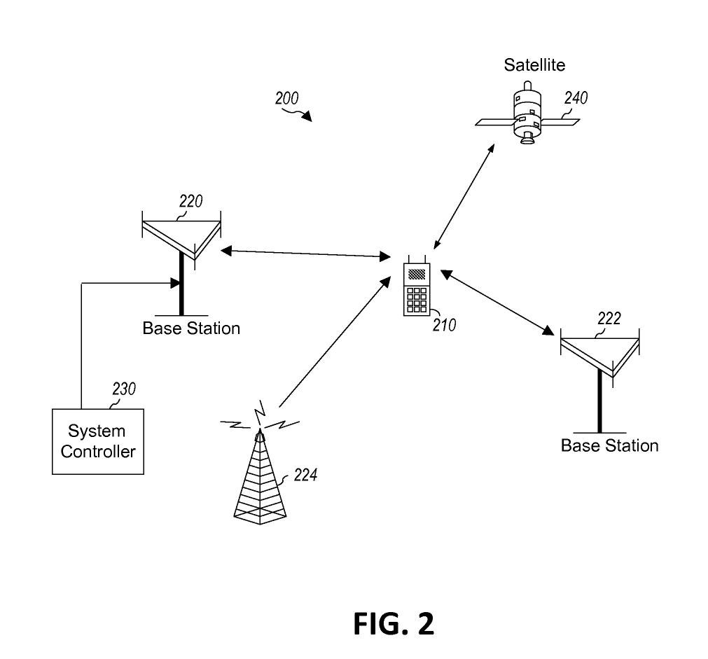

FIG. 2 is an exemplary wireless device 210 communicating with a wireless communication system 200. Wireless communication system 200 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 2 shows wireless communication system 200 including two base stations 220 and 222 and one system controller 230. In general, a wireless system may include any number of base stations and any set of network entities.

Wireless device 210 may also be referred to as a user equipment (UE), a mobile station, a terminal, an access terminal, a subscriber unit, a station, etc. Wireless device 210 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 210 may communicate with wireless system 200. Wireless device 210 may also receive signals from broadcast stations (e.g., broadcast station 224), signals from satellites (e.g., satellite 240) in one or more global navigation satellite systems (GNSS), etc. Wireless device 210 may support one or more radio technologies for wireless communication including LTE, WCDMA, CDMA 1X, EVDO, TD-SCDMA, GSM, 802.11, etc.

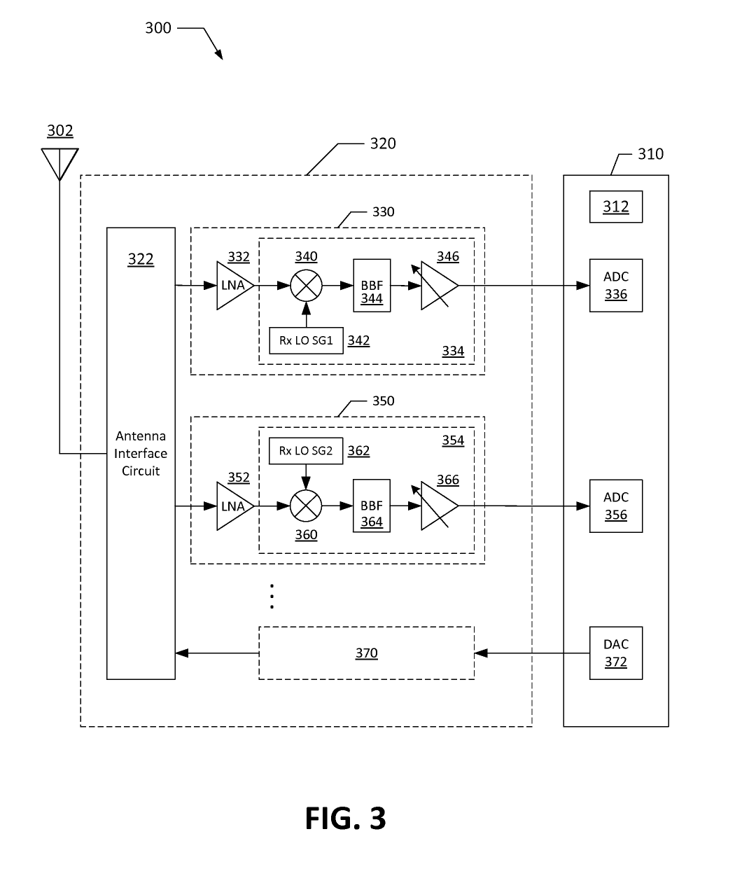

FIG. 3 is a functional block diagram of an exemplary design of a wireless device 300 that is one embodiment of a wireless device 210 of FIG. 2. In this exemplary design, the wireless device 300 includes a transceiver 320 coupled to an antenna 302, and a data processor/controller 310 having a memory unit 312 to store data and program codes. The transceiver 320 may include, among other blocks, antenna interface circuit 322, a plurality of receivers including a receiver 330 and a second receiver 350, and at least one transmitter 370 to support bi-directional communication. In general, the wireless device 300 may include any number of transmitters and receivers for any number of communication systems and frequency bands. The data processor/controller 310 may include, among other blocks, a memory unit 312. The data processor/controller 310 may also include at least one analog-to-digital converter (ACD) 336, 356 coupled to the receivers 330, 350, respectively, and at least one digital-to-analog converter (DAC) 372 couple to the at least one transmitter 370. The data processor/controller 310 may perform various functions for the wireless device 300. For example, the data processor/controller 310 may perform processing for data being received via the receiver 330, 350 and data being transmitted via the transmitter 370. The data processor/controller 310 may also control the operation of various circuits within the transceiver 320. The ADC 336 or 356 converts the analog input signal received from the receiver 330 or 350 to the digital data. The DAC 372 converts the digital data generated in the data processor/controller 310 to an analog output signal and provides the converted analog output signal to the transmitter 370. Memory unit 312 may store program codes and data for the data processor/controller 310. The data processor/controller 310 may be implemented on one or more application specific integrated circuits (ASICs) anchor other integrated circuits (ICs).

In the illustrated embodiment of FIG. 3, the first receiver 330 includes a first low noise amplifier (LNA) 332 and a first receive circuit 334. The first receive circuit 334 includes a first mixer/downconverter 340, a first receiver local oscillator signal generator (Rx LO SG1) 342, and a first baseband filter 344, which may be configured as a low-pass filter. The first receive circuit 334 may also include a first controllable amplifier 346 such as a variable gain amplifier or trans-impedance amplifier. The variable gain amplifier may be configured to provide automatic gain based on a control signal from the data processor/controller 310. The trans-impedance amplifier may be configured as a current-to-voltage converter. In some embodiments, the controllable amplifier 346 can be omitted. The Rx LO SG1 342 in the receiver 330 may receive a clock signal from the data processor/controller 310 through a phase-locked loop circuit.

The second receiver 350 is configured similarly to the first receiver 330. The second receiver 350 includes a second LNA 352 and a second receive circuit 354. The second receive circuit 354 includes a second mixer/downconverter 360, a second receiver local oscillator signal generator (Rx LO SG2) 362, and a second baseband filter 364, which may be configured as a low-pass filter. The second receive circuit 354 may also include a second controllable amplifier 366 such as a variable gain amplifier or trans-impedance amplifier. In sonic embodiments, the second controllable amplifier 366 can be omitted. The Rx LO SG2 364 in the second receiver 350 may receive a clock signal from the data processor/controller 310 through a phase-locked loop circuit.

For data reception, antenna 302 receives signals from base stations and/or other transmitter stations and provides a received RF signal, which is routed through an antenna interface circuit 322 and presented as an input RF signal to the receivers 330, 350. The antenna interface circuit 322 may include switches, duplexers, transmit filters, receive filters, matching circuits, etc. Within the receiver 330, 350, the LNA 332, 352 amplifies the input RF signal and provides an output RF signal to the mixer/downconverter 340, 360. The Rx 342, 362 generates a local oscillator signal. The mixer/downconverter 340, 360 mixes the output RF signal with the generated local oscillator signal to downconvert the output RF signal from RF to baseband. The baseband filter 344, 364 filters the baseband signal to provide filtered baseband signal to the controllable amplifier 346, 366. The analog output of the controllable amplifier 346, 366 is then provided to the ADC 336, 356. In some embodiments in which the controllable amplifier is omitted, the analog output of the baseband filter 344, 364 is provided directly to the ADC 336, 356. In other embodiments, the receiver 330, 350 may also include other elements such as matching circuits, oscillators, and other similar elements needed for the operation of the receiver 330, 350.

For data transmission, the data processor/controller 310 processes (e.g., encodes and modulates) data to be transmitted and provides a digital data to the DAC 372, which converts the digital data to a baseband analog output signal and provides the converted analog output signal to the transmitter 370, which generates a transmit RF signal. The RF signal is routed through the antenna interface circuit 322 and transmitted via antenna 302. The transmitter 370 may also include other elements such as matching circuits, oscillators, and other similar elements needed for the operation of the transmitter 370.

FIG. 3 shows an exemplary transceiver design. In general, the conditioning of the signals in a transmitter and a receiver may be performed by one or more stages of amplifier, filter, upconverter, downconverter, etc. These circuit blocks may be arranged differently from the configuration shown in FIG. 3. Furthermore, other circuit blocks not shown in FIG. 3 may also be used to condition the signals in the transmitter and receiver. Some circuit blocks in FIG. 3 may also be omitted. All or a portion of the transceiver 320 may be implemented on one or more analog integrated circuits (ICs), RF ICs (RFICs), mixed-signal ICs, etc.

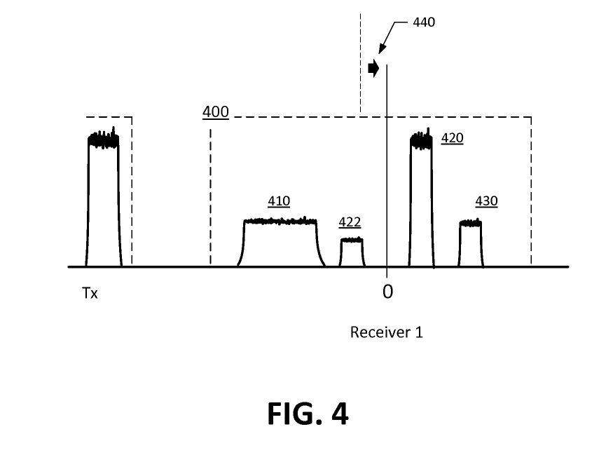

In one embodiment, to address the issues with in-band jammers falling inside the image of the wanted signal for a ZIF wideband receiver that digitizes multiple carriers in a single ADC (see FIG. 1A), a local oscillator (LO) frequency of a receiver (Rx) can be re-programmed or re-tuned to a different frequency. For example, FIG. 4 shows a single receiver case 400 including a jammer signal 420 in the presence of a non-contiguous intra-band PCC 410 and a non-contiguous intra-band SCC 430 of a wanted signal. In the single receiver case 400 of FIG. 4 the LO frequency of the Rx is re-programmed (see arrow 440) to a different frequency so that e RSB image 422 of the jammer signal 420 is moved out of the bandwidth of the wanted signal 410. Thus, in contrast to FIG. 1A, in which the RSB image 122 appeared on the wanted signal 110, FIG. 4 shows that the RSB image 422 of the jammer signal 420 has moved out of the bandwidth of the wanted signal 410.

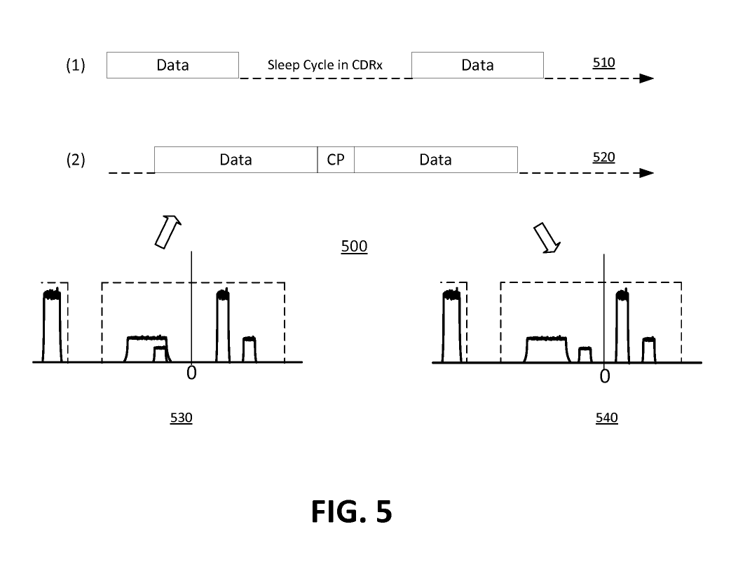

However, re-programming the LO frequency of the Rx during data reception may cause an undesirable drop in the data throughput. Therefore, the LO frequency of the Rx can be re-programmed during gaps in the data transmission. For example, FIG. 5 shows a process 500 of re-programming of the LO frequency performed during gaps in the data transmission by shifting the LO frequency from a first frequency shown in 530 to a second frequency shown in 540. As stated before, the re-programming or shifting of the LO frequency may be performed during following gaps in the data transmission so that the throughput is not affected: (1) during the sleep mode of a CDRx cycle (see process 510); or (2) during the CP of an OFDM symbol using fast hopping PLL to save power (see process 520). However, since above-cited gaps are for examples only, re-programming of the LO frequency can be done during any gaps in the data transmission.

Accordingly, embodiments of the present disclosure are directed to a receiver including an LO and a controller which adjusts the frequency of the LO in response to the presence of intra-band jammers that fall within the bandwidth of a baseband filter so that the image of an intra-band jammer does not fall on one of the wanted signals. The bandwidth of the baseband filter is configured to be wide enough to accommodate multiple received channels and intra-band jammers. In one embodiment, the adjustment of the LO frequency is performed during the CP of an OFDM symbol. In another embodiment, the adjustment of the LO frequency is performed during the sleep mode of the CDRx cycle.

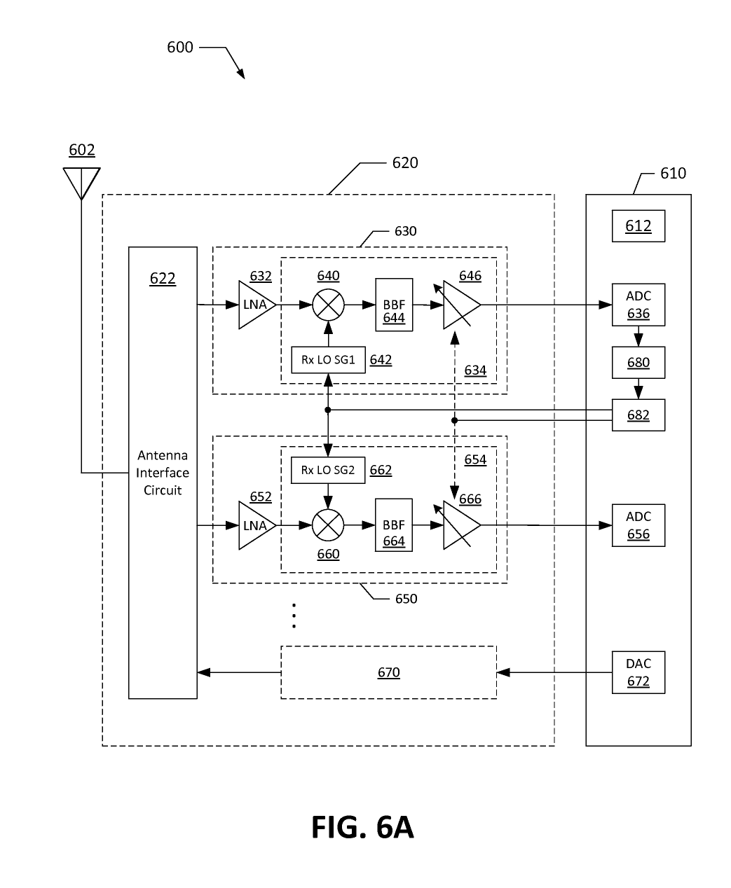

FIG. 6A is a functional block diagram of an exemplary design of a wireless device 600 that is one embodiment of a wireless device 210 of FIG. 2. In the exemplary design, the wireless device 600 is configured with a transceiver 620 which includes ZIF wideband receivers 630, 650. The receiver 630 is a first ZIF wideband receiver, while the receiver 650 is a second ZIF wideband receiver.

The wireless device 600 may include a transceiver 620 coupled to an antenna 602, and a data processor/controller 610 having a memory unit 612 to store data and program codes. The transceiver 620 may include, among other blocks, antenna interface circuit 622, a plurality of receivers including a first ZIF wideband receiver 630 and the second ZIF wideband receiver 650, and at least one transmitter 670 to support bi-directional communication. In general, the wireless device 600 may include any number of transmitters and receivers for any number of communication systems and frequency bands. The data processor/controller 610 may include, among other blocks, a memory unit 612, at least one ADC 636, 656 coupled to the receivers 630, 650, respectively, and at least one DAC 672 couple to the at least one transmitter 670. The data processor/controller 610 may also include a jammer detector 680 and a frequency shifter 682.

In the illustrated embodiment of FIG. 6A, the first ZIF wideband receiver 630 includes a first LNA 632 and a first receive circuit 634. The first receive circuit 634 includes a first mixer/downconverter 640, a first Rx LO SG1 642, and a first baseband filter 644, which may be configured as a low-pass filter. The first receive circuit 634 may also include a first controllable amplifier 646 such as a variable gain amplifier or trans-impedance amplifier. The Rx LO SG1 642 in the first wideband ZIF receiver 630 may receive a clock signal from the data processor/controller 610 through a phase-locked loop circuit. The second ZIF wideband receiver 650 is configured similarly to the first ZIF wideband receiver 630. The second receiver 650 includes a second LNA 652 and a second receive circuit 654. The second receive circuit 654 includes a second mixer/downconverter 660, a second Rx LO SG2 662, and a second baseband filter 664, which may be configured as a low-pass filter. The second receive circuit 654 may also include a second controllable amplifier 666 such as a variable gain amplifier or trans-impedance amplifier. The Rx LO SG2 664 in the second receiver 650 may receive a clock signal from the data processor/controller 610 through a phase-locked loop circuit. In some embodiments, the first mixer/downconverter 640 is configured as an in-phase downconverter, while the second mixer/downconverter 660 is configured as a quadrature-phase downconverter.

The jammer detector 680 in the data processor/controller 610 may be configured to detect the presence of interfering signals in the vicinity of a wanted signal. The interfering signals may be referred to as jammers, blocker, or interferers. Thus, when the jammer detector 680 detects an interfering signal above a pre-defined threshold, a detect signal may be sent to the frequency shifter 682. The frequency shifter 682 is configured to receive the detect signal from the jammer detector 680 and trigger signals from the processor/controller 610 indicating gaps in the data transmission. In one embodiment, a first trigger signal is received at the frequency shifter 682 when the wireless device 600 enters the sleep mode of the CDRx cycle. In another embodiment, a second trigger signal is received at the frequency shifter 682 during the CP of an OFDM symbol.

In one embodiment, when the frequency shifter 682 receives a positive detect signal from the jammer detector 680 and at least one trigger signal indicating at least one gap in the data transmission, the frequency shifter 682 re-programs the LO frequency of the Rx to a different frequency by controlling the Rx LO SG1 642 and the Rx LO SG2 662. In another embodiment, the re-programming of the LO frequency by the frequency shifter 682 is done when just the positive detect signal is received from the jammer detector 680. The frequency shifter 682 may also be configured to adjust the phase of the LO by controlling the digital rotators including the controllable amplifiers 646, 666.

FIG. 6B is a functional block diagram of a wireless device 690 in accordance with an alternative embodiment of the present disclosure. In the illustrated embodiment of FIG. 6B, the wireless device 690 is configured with a single/combined receiver 692, but with separate mixers/downconverters 693, 694, LO signal generators 695, 696, and baseband filters 697, 698. Thus, in this embodiment, both mixers/downconverters 693, 694 would receive input from a single LNA 691. The remainder of the wireless device 690 includes same modules and operates in same manner as the wireless device 600.

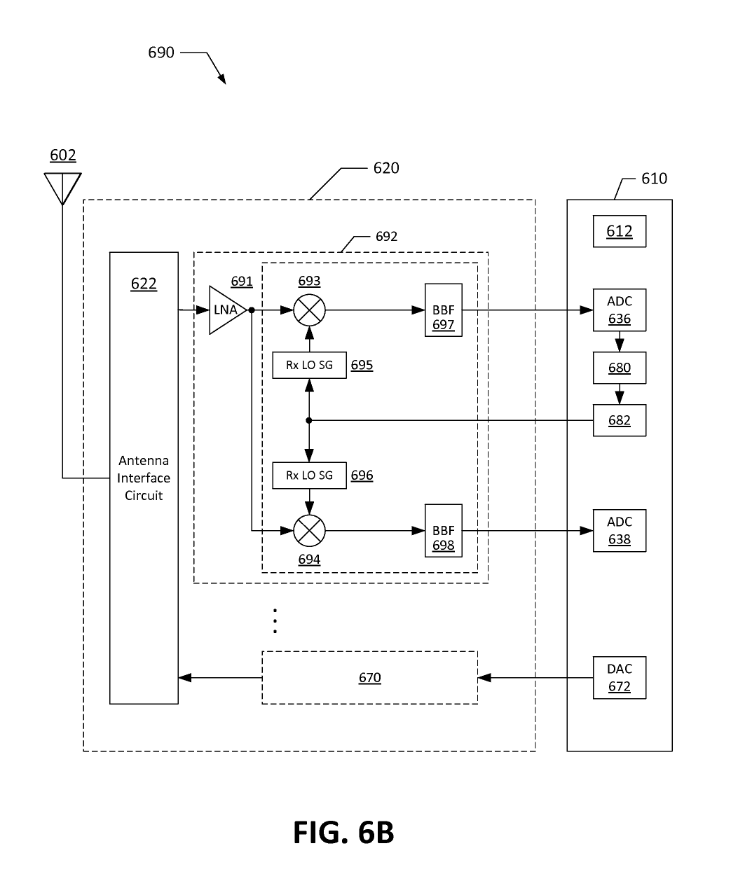

FIG. 7 is a functional block diagram of a receiver 700 in accordance with one embodiment of the present disclosure. The receiver 700 may include a mixer (or downconverter) 720, a baseband filter 730, a local oscillator (LO) 740, and a controller 750. The mixer 720 receives the amplified RF signal from an LNA 710. The output of the baseband filter 730 couples to a processor 760. In an alternative embodiment, the baseband filter 730 couples to the controller 750 such that the controller 750 performs the functions of a processor such as jammer detection and data transmission gap detection.

In the illustrated embodiment of FIG. 7, the controller 750 is configured to adjust the frequency of the LO 740 in response to the presence of intra-band jammers that fall within the bandwidth of a baseband fiber 730 so that the image of an intra-band jammer does not fall on one of the wanted signals. The bandwidth of the baseband filter 730 is configured to be wide enough to accommodate multiple received channels and intra-band jammers. In one embodiment, the adjustment of the LO frequency is performed during the CP of an OFDM symbol. In another embodiment, the adjustment of the LO frequency is performed during the sleep mode of the CDRx cycle.

In one embodiment: the mixer 720 is configured to receive an input signal having a first frequency; the LO 740 is configured with an LO frequency and operates with the mixer 720 to change the first frequency of the input signal to a second frequency; the baseband filter 730 is coupled to the local oscillator 740 and has a bandwidth; and the controller 750 is coupled to the LO 740 and is configured to detect the presence of intra-band jammers or blockers that fall within the bandwidth of the baseband filter 730. The controller 750 is also configured to detect gaps in the data transmission. In an alternative, the controller 750 is configured to receive a detect signal which signifies the presence of intra-band jammers or blockers that fall within the bandwidth of the baseband filter 730, and to receive triggers signals which indicate gaps in the data transmission. The detect signal and the trigger signals may be processed by the processor 760 and transmitted to the controller 750.

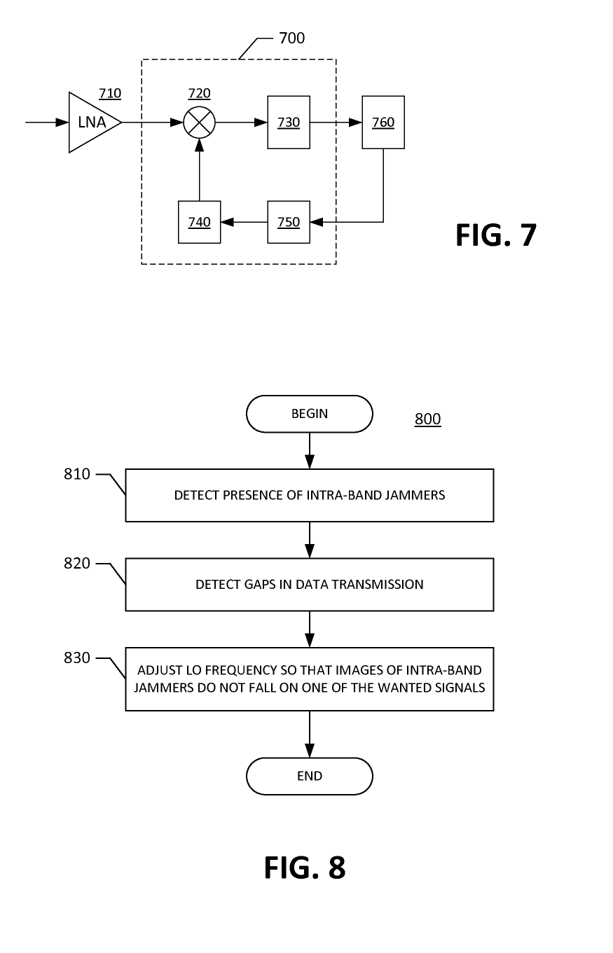

FIG. 8 is a functional flow diagram illustrating a method 800 for adjusting the LO frequency in the presence of intra-band jammers in accordance with one embodiment of the present disclosure. In the illustrated embodiment of FIG. 8, the method 800 includes detecting presence of intra-band jammers or blockers that fall within the bandwidth of a baseband filter, at block 810. In an alternative, a jammer detect signal is received indicating the presence of intra-band jammers or blockers. The gaps in the data transmission are then detected, at block 820. In an alternative, a gap detect signal is received indicating a gap in the data transmission. In one embodiment, the gap in the data transmission includes the CP of an OFDM symbol. In another embodiment, the gap includes the sleep mode of the CDRx cycle. At block 830, the frequency of the local oscillator is adjusted so that the images of the intra-band jammers do not fall on one of the wanted signals. The bandwidth of the baseband filter is configured to be wide enough to accommodate multiple received channels and intra-band jammers.

Although several embodiments of the disclosure are described above, many variations of the disclosure are possible. For example, although the illustrated embodiments are configured to adjust the LO frequency during gaps in the data transmission, the LO frequency can be adjusted during the transmission of data if the data throughput is not a problem. Further, features of the various embodiments may be combined in combinations that differ from those described above. Moreover, for clear and brief description, many descriptions of the systems and methods have been simplified. Many descriptions use terminology and structures of specific standards. However, the disclosed systems and methods are more broadly applicable.

Those of skill will appreciate that the various illustrative blocks and modules described in connection with the embodiments disclosed herein can be implemented in various forms. Some blocks and modules have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the disclosure. In addition, the grouping of functions within a module, block, or step is for ease of description. Specific functions or steps can be moved from one module of block without departing from the disclosure.

The above description of the disclosed embodiments is provided to enable any person skilled in the art to make or use the disclosure. Various modifications to these embodiments will be readily apparent to those skilled in the art, and the generic principles described herein can be applied to other embodiments without departing from the spirit or scope of the disclosure. Thus, it is to be understood that the description and drawings presented herein represent presently preferred embodiments of the disclosure and are therefore representative of the subject matter which is broadly contemplated by the present disclosure. It is further understood that the scope of the present disclosure fully encompasses other embodiments that may become obvious to those skilled in the art and that the scope of the present disclosure is accordingly limited by nothing other than the appended claims.

1. A zero intermediate frequency (ZIF) receiver, comprising:
a local oscillator (LO) configured to generate an LO signal with a frequency;
a mixer coupled to the LO, the mixer configured to change a first frequency of an input signal to a second frequency based on the frequency of the generated LO signal, the input signal including a plurality of wanted signals;
a baseband filter coupled to the mixer and having a bandwidth; and
a controller coupled to the local oscillator, the controller configured to shift the frequency of the LO signal to a third frequency in response to a presence of one or more intra-band jammers that fall within the bandwidth of the baseband filter,
wherein the frequency of the LO signal is shifted to the third frequency to shift respective residual sideband image of the one or more intra-band jammers so that the respective residual sideband image is not present within a respective one of the plurality of wanted signals.

2. The receiver of claim 1, wherein the plurality of wanted signals are received via a plurality of channels.

3. The receiver of claim 2, wherein the bandwidth of the baseband filter is configured to accommodate the plurality of channels and the one or more intra-band jammers.

4. The receiver of claim 1, wherein the mixer comprises a downconverter configured to shift the first frequency of the input signal to a lower frequency.

5. The receiver of claim 4, wherein the downconverter comprises an in-phase downconverter and a quadrature-phase downconverter.

6. The receiver of claim 1, wherein the controller is further configured to detect the presence of the one or more intra-band jammers which fall within the bandwidth of the baseband filter.

7. The receiver of claim 1, wherein the controller is further configured to receive a detect signal which signifies the presence of the one or more intra-band jammers which fall within the bandwidth of the baseband filter.

8. The receiver of claim 1, wherein the controller is configured to adjust the frequency of the LO signal venerated by the LO during a gap in data transmission of the ZIF receiver in response to the presence of the one or more intra-band jammers that fall within the bandwidth of the baseband filter.

9. The receiver of claim 8, wherein the controller is configured to detect the gap in the data transmission.

10. The receiver of claim 8, wherein the controller is configured to receive triggers signals which indicate the gap in the data transmission.

11. The receiver of claim 8, wherein the gap in the data transmission comprises a time period of a cyclic prefix (CP) of an orthogonal frequency division multiplexing (OFDM) symbol.

12. The receiver of claim 8, wherein the gap in the data transmission comprises a sleep mode of a connected discontinuous reception (CDRx) cycle.

13. A method of shifting a local oscillator frequency in the presence of intra-band jammers in a zero intermediate frequency (Z(F) receiver, the method comprising:
receiving an input signal including a plurality of wanted signals;
receiving an indication of a presence of one or more intra-band jammers that fall within a bandwidth of a baseband filter; and
shifting the local oscillator (LO) frequency of an LO signal in response to the presence of the one or more intra-band jammers that fall within the bandwidth of the baseband filter,
wherein the LO frequency of the LO signal is shifted to another frequency to shift a respective residual sideband image of the one or more intra-band jammers so that the respective sideband image is not present within a respective one of the plurality of wanted signals.

14. The method of claim 13, further comprising
receiving the plurality of wanted signals using a plurality of channels.

15. The method of claim 14, further comprising
setting the bandwidth of the baseband filter to accommodate the plurality of channels and the intra-band jammers.

16. The method of claim 13, wherein receiving an indication comprises
detecting the presence of the one or more intra-band jammers which fall within the bandwidth of the baseband filter.

17. The method of claim 13, further comprising
adjusting the LO frequency during a gap in data transmission of the ZIF receiver.

18. The method of claim 17, further comprising
detecting the gap in the data transmission.

19. The method of claim 17, further comprising
receiving triggers signals which indicate the gap in the data transmission.

20. The method of claim 17, wherein the gap in the data transmission comprises a time period a cyclic prefix (CP) of an orthogonal frequency division multiplexing (OFDM) symbol.

21. The method of claim 17, wherein the gap in the data transmission comprises a sleep mode of a connected discontinuous reception (CDRx) cycle.

22. The method of claim 17, wherein the gap in the data transmission comprises a gap used in one of inter, intra, or inter-radio access technologies (inter-RAT) frequency measurements.

23. The method of claim 17, wherein the gap in the data transmission comprises a gap scheduled by a base station or gaps detected by a user equipment (UE).

24. An apparatus for shifting a local oscillator (LO) frequency in the presence of intra-band jammers in a zero intermediate frequency (ZIF) receiver, the apparatus comprising:
means for receiving an input signal including a plurality of wanted signals;
means for receiving an indication of a presence of one more intra-band jammers that fall within a bandwidth of a baseband filter; and
means for shifting the LO frequency of an LO signal in response to the presence of the one or more intra-band jammers that fall within the bandwidth of the baseband filter,
wherein the LO frequency of the LO signal is shifted to another frequency to shift a respective residual sideband image of the one or more intra-band jammers so that the respective sideband image is not present within a respective one of the plurality of wanted signals.

25. The apparatus of claim 24, further comprising
means for receiving the plurality of wanted signals using a plurality of channels.

26. The apparatus of claim 25, further comprising
means for setting the bandwidth of the baseband filter to accommodate the plurality of channels and the intra-band jammers.

27. The apparatus of claim 24, wherein means for receiving an indication comprises
means for detecting the presence of the intra-band jammers which fall within the bandwidth of the baseband filter.

28. The apparatus of claim 24, further comprising
mean for adjusting the LO frequency during gaps in data transmission of the ZIF receiver.

29. The apparatus of claim 28, further comprising
means for detecting the gaps in the data transmission.

30. The method of claim 28, further comprising means for receiving triggers signals which indicate the gaps in the data transmission.
